(19) United States
(12) Patent Application Publication
(10) Pub. No.: US 2008/0186741 A1
(43) Pub. Date: Aug. 7, 2008

(54) METHOD AND SYSTEM ADAPTED TO REGENERATE LOAD ENERGY IN AC-TO-DC AND DC-TO-AC POWER CONVERTER SYSTEMS

(76) Inventor: Mark Rabo, Mississauga (CA)

Correspondence Address: Murata Power Solutions;c/o Keating & Bennett, LLP, 8180 Greensboro Drive, Suite 850, McLean, VA, 22102, US

(21) Appl. No.: 12/024,982

(22) Filed: Feb. 1, 2008

Related U.S. Application Data
(60) Provisional application No. 60/887,886, filed on Feb. 2, 2007.

(51) Int. Cl. H02M 7/00; G01R 31/02

(52) U.S. Cl. 363/13; 324/537

(57) ABSTRACT

An energy regenerating system includes a converter, an inverter, and a supplemental power source. The converter and the inverter are electrically connected to each other to define an electrical loop such that energy of the energy regenerating system is regenerated. The converter, the inverter, and the supplemental power source are arranged such that, when current flows in the electrical loop, the converter is a load on the inverter and the inverter is a load on the converter. The supplemental power source is arranged to replenish energy losses in the energy regeneration system, including energy losses in the electrical loop caused by the converter and the inverter.

### BACKGROUND OF THE INVENTION

1. Field of the Invention

The present invention generally relates to power recycling in burn-in racks, electronic loads, and test systems, and more particularly relates to controlling and recycling power in electronic devices, such as AC-to-DC power supplies, burn-in racks, automatic test equipment (ATE), electronic loads, power converters, power inverters, and other electrical devices.

2. Description of the Related Art

With the expansion of telecommunication industries, consumer electronics, computers, and other similar fields, the need for power sources that are capable of supplying energy at higher levels is rapidly increasing. At the same time, the rising cost of electric power and the necessity to reduce pollution in the environment require new and innovative ways to conserve energy. During the testing and burn-in of power converting devices, a huge amount of energy is wasted on passive loads. This wasted energy adds to the increased cost of manufacturing and to the degradation of the environment. Although there are already effective power regenerating systems and methods for DC-to-DC conversion, there is currently no simple and inexpensive solution to recycle power from AC-to-DC and DC-to-AC power converter systems.

A conventional system 18 is shown in FIG. 1. The conventional system 18 includes an AC-to-DC power converter 12, herein referred to as a “converter,” connected to a passive load 20. Another conventional system 19 is shown in FIG. 2. Conventional system 19 includes a DC-to-AC inverter 14, herein referred to as an “inverter,” connected to a passive load 20. Typically, a resistive load is used as the passive load 20 in the conventional systems 18 and 19. However, any load that simply absorbs and dissipates the energy can be used as the passive load. Passive loads do not recycle, return back, regenerate, or recover any part or all of the power delivered to them.

As shown in FIG. 1, the total energy loss in the conventional system 18 is 1100 W. Converter 12 dissipates 100 W, almost all of which is wasted in the form of heat, and load 20 dissipates 1000 W of energy, almost all of which is wasted in the form of heat. That is, all of the energy inputted into the converter 12 is dissipated.

As shown in FIG. 2, the total energy loss in the conventional system 19 is also 1100 W. Inverter 14 dissipates 100 W, almost all of which is wasted in the form of heat, and load 20 dissipates 1000 W of energy, almost all of which is wasted in the form of heat. That is, all of the energy inputted into the inverter 14 is dissipated.

The consumption of power during testing of power supplies can be large. To recycle power, some known energy recycling and testing systems feed excess power back to the utility power grid, but these systems are complicated and costly.

### SUMMARY OF THE INVENTION

To overcome the problems described above, preferred embodiments of the present invention provide an energy regenerating system and a method of testing a unit under test.

The energy regenerating system according to preferred embodiments of the present invention include a converter, an inverter, and a supplemental power source. The converter and the inverter are electrically connected to each other to define an electrical loop such that energy of the energy regenerating system is regenerated. The converter, the inverter, and the supplemental power source are arranged such that, when current flows in the electrical loop, the converter is a load on the inverter and the inverter is a load on the converter. The supplemental power source is arranged to replenish energy losses in the energy regeneration system, including energy losses in the electrical loop caused by the converter and the inverter.

The supplemental power source preferably outputs DC power. The output of the supplemental power source is preferably connected to DC terminals of the converter and the inverter. The energy regenerating system preferably includes at least one additional converter arranged in an array with the inverter, converter, and supplemental power source, where the AC terminals of the inverter, the converter, and the at least one additional converter are connected. The energy regenerating system preferably includes at least one additional inverter arranged in an array with the inverter, converter, and supplemental power source, where the DC terminals of the converter, the inverter, and the at least one additional inverter are connected.

The inverter preferably outputs a pure sine wave, a modified sine wave, a quasi sine wave, a square wave, and/or a combination thereof.

The converter preferably includes power factor correction circuitry. The converter is preferably arranged such that adjustments to parameters of the converter control a load current in the electrical loop. The supplemental power source is preferably arranged such that adjustments to parameters of the supplemental power source control a load current in the electrical loop. The supplemental power source is preferably arranged such that adjustments to parameters of the supplemental power source control the magnitude of a load current in the electrical loop. The supplemental power source is preferably arranged such that adjustments to parameters of the supplemental power source control the direction of a load current in the electrical loop.

The output of the supplemental power source and the DC terminal of the converter are preferably configured to control a load current in the electrical loop. The energy regenerating system further includes a control circuit arranged to control a load current in the electrical loop. The energy regenerating system preferably includes a control circuit arranged to provide control, supervisory, measurement, or protection functions.

The method of testing a unit under test according to preferred embodiments of the present invention include providing a testing system, which includes a converter an inverter; and a supplemental power source and where the unit under test is the converter, the inverter, or the supplemental power source, connecting the converter and the inverter to each other to define an electrical loop such that energy is regenerated, connecting the supplemental power source to the electrical loop to replenish energy losses in the testing system, including energy losses caused by the converter and the inverter, and testing the unit under test by causing current to flow in the electrical loop.

The method of testing a unit under test preferably includes the step of adjusting at least one parameter of the supplemental power source to control a load current in the electrical loop. The method of testing a unit under test preferably includes the step of adjusting at least one parameter of the supplemental power source to control the magnitude of a load current in the electrical loop.

The method of testing a unit under test preferably includes the step of adjusting a voltage potential difference between an output of the supplemental power source and a DC terminal of the converter to control a load current in the electrical loop. The method of testing a unit under test preferably includes the step of adjusting a voltage polarity between an output of the supplemental power source and a DC terminal of the converter to control a load current in the electrical loop. The method of testing a unit under test preferably includes the step of adjusting the power output of the supplemental power source to control the magnitude of the load current in the electrical loop.

Other features, elements, characteristics, and advantages of the present invention will become more apparent from the following detailed description of preferred embodiments of the present invention with reference to the attached drawings.

### BRIEF DESCRIPTION OF THE DRAWINGS

FIG. 1 is a block diagram showing a conventional converter connected to a passive load.

FIG. 2 is a block diagram showing a conventional inverter connected to a passive load.

FIG. 3 is a block diagram showing an energy regenerating system in accordance with a preferred embodiment of the present invention.

FIG. 4 is a block diagram showing an example of energy distribution by the conventional converter and load shown in FIG. 1.

FIG. 5 is a block diagram showing an example of energy distribution by the conventional inverter and load shown in FIG. 2.

FIG. 6 is a block diagram showing an example of power distribution in the regenerating system shown in FIG. 3.

FIG. 7 is a block diagram showing an additional preferred embodiment of the present invention in which an array of converters and inverters are used.

FIG. 8 is a graph showing the input power from the supplemental power source versus recycled power in the energy recycling loop for an example of the preferred embodiments of the present invention.

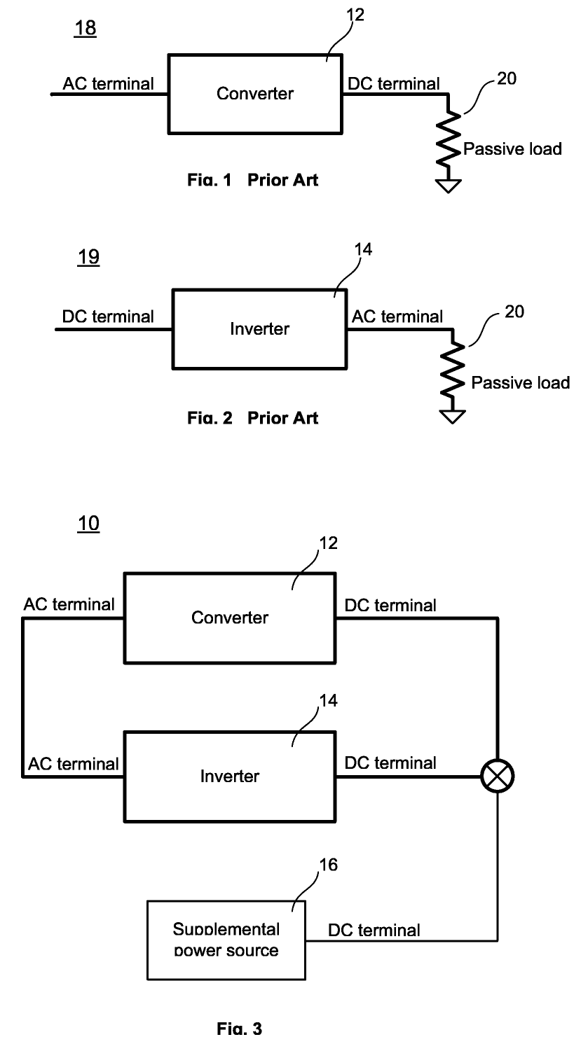

### DETAILED DESCRIPTION OF PREFERRED EMBODIMENTS

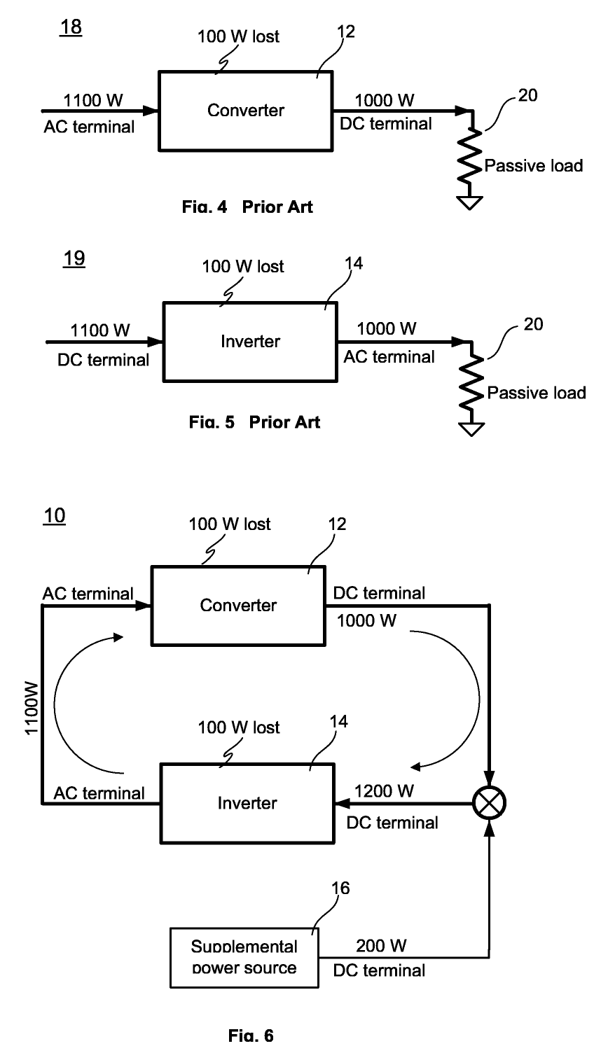

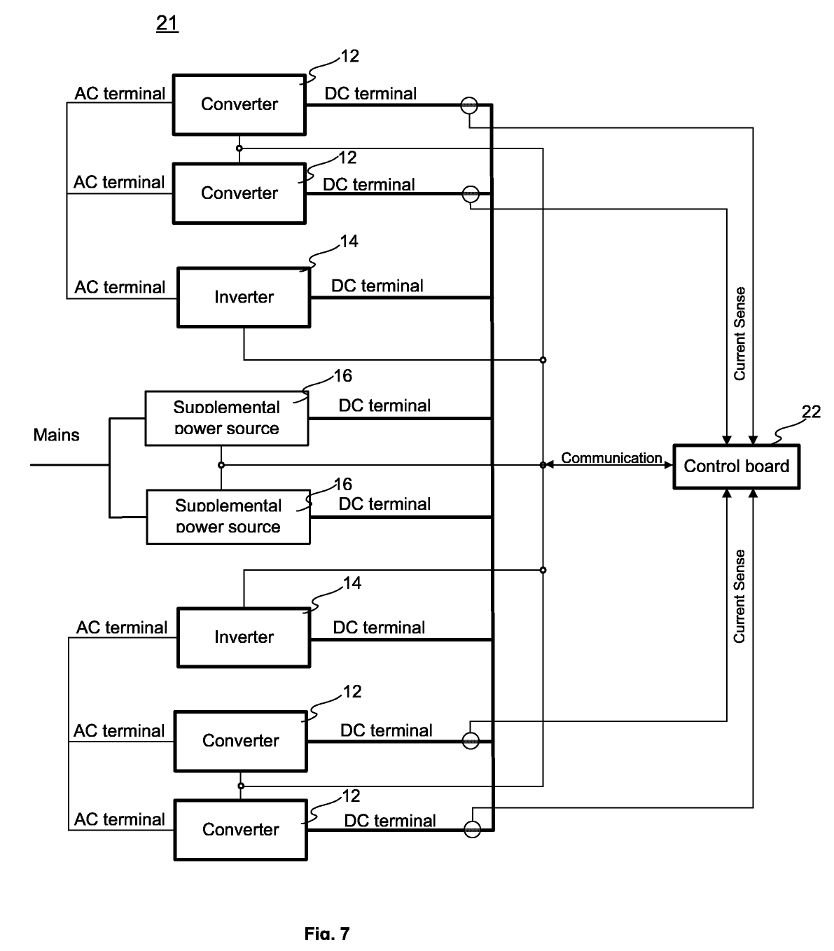

An energy regenerating system 10 and 21 according to various preferred embodiments of the present invention will be discussed with reference to FIGS. 3, 6, and 7.

As shown in FIG. 3, an energy regenerating system 10 according to a preferred embodiment of the present invention preferably includes a converter 12, an inverter 14, and supplemental power source 16. The AC terminal of converter 12 is connected to the AC terminal of the inverter 14. The DC terminal of inverter 14 is connected to the DC terminal of the converter 12. This arrangement of converter 12 and inverter 14 creates a continuous energy recycling loop. The energy regenerating system 10 preferably also includes a supplemental power source 16. The supplemental power source 16 replenishes the energy losses of the energy regenerating system 10 caused by the limited efficiencies of the individual components and devices operating within the energy regenerating system 10.

With this arrangement, the converter 12, the inverter 14, the supplemental power source 16, or a combination thereof can be a unit or units under test. Further, the converter 12 acts as a load on the inverter 14 and the inverter 14 acts as a load on the converter 12.

The current in the energy recycling loop formed by the inverter 14 and converter 12 can be either clockwise or counter-clockwise, depending on the output parameters of the supplemental power source 16 and the converter 12.

Starting the energy regenerating system 10 requires a short burst of power delivered by supplemental power source 16 into the energy recycling loop. First, the inverter 14 is powered up, which then powers up the converter 12. Once the operation of the energy recycling loop is established, the energy recycling loop current depends on the power delivered to the energy recycling loop by the supplementary power source 16. To shut down the system, the power from the supplemental source 16 can be turned off, or either the converter 12 or inverter 14 can be turned off.

Instead of using a single converter 12 or a single inverter 14, multiple converters 12 or multiple inverters 14 can be used. For example, multiple converters 12 can be arranged in an array such that the AC terminal of the inverter 14 is connected to each AC terminal of the converters 12, and each DC terminal of the converters 12 is connected to the DC terminal of the 14 inverter or multiple inverters 14. It is also possible to use an array of converters 12 connected such that the DC terminals of the converters 12 is connected to one or more DC terminals of the inverters 14. It is also possible to use multiple converters 12 and multiple inverters 14, where the number of converters 12 can be the same as or different from the number of inverters 12. It is also possible to use multiple supplemental power supplies 16.

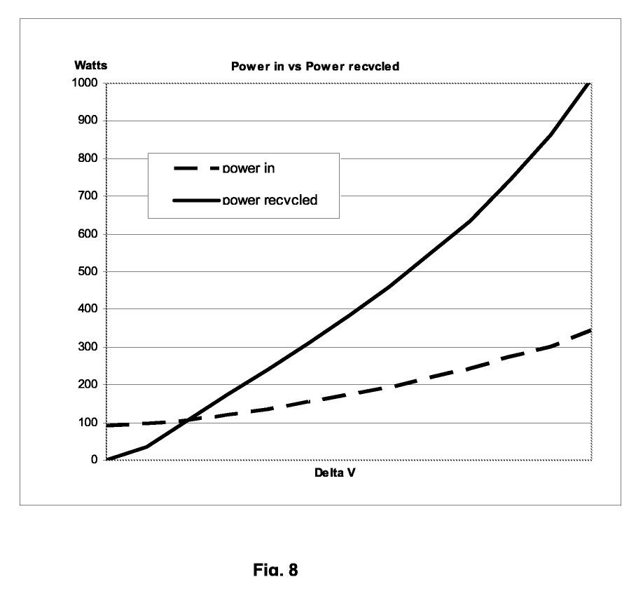

FIG. 7 shows an energy regenerating system 21 that includes an array of four converters 12 and two inverters 14. Two of the converters 12 are connected to one of the inverters 14, and two of the converters 12 are connected to another of the inverters 14. In FIG. 7, the converters 12 are preferably units under test and the inverters 14 preferably act as loads. The two supplemental power supplies 16 replenish the energy losses of the energy regenerating system 21 caused by the limited efficiencies of the individual components and devices operating within the energy regenerating system 21.

As seen in FIG. 7, the energy regenerating system 21 can include a control board 22 that controls the load current in the energy recycling loop. The control board 22 can also provide protective, measurement, supervisory, control, etc. functions in addition to the load current control function. Although not shown in FIGS. 3 and 6, the energy regenerating system 10 can include a control board that provides functions similar to the functions of control board 22. The configuration of the control board 22 shown in FIG. 7 is only one example of many possible configurations that could be used.

The load current magnitude in the energy recycling loop and the loading effect of the inverter 14 on the converter 12 and the loading effect of the converter 12 on the inverter 14 can be controlled by altering the parameters of the supplemental power source 16, including the output power that is fed into the energy recycling loop. For example, the magnitude and direction of the load current flow in the energy recycling loop can be controlled by altering the voltage potential difference between the output of the supplemental power source 16 and the converter 12 and/or the voltage polarity on the outputs of the supplemental power source 16 and of the converter 12 (or the input of the inverter 14).

The load current flowing in the energy recycling loop, and thus the power distributed in the energy recycling loop, is directly proportional to the difference in output potentials between the supplementary power source 16 and the converter 12. When the potential difference is approaching zero (or is zero, minimal, or no load current flows in the energy recycling loop), the amount of energy from the supplementary power source 16 that is necessary to sustain the operation of the closed energy recycling loop is at a minimum.

FIG. 8 is a graph showing the input power from the supplemental power source versus recycled power in the energy recycling loop for an example of the preferred embodiments of the present invention. In FIG. 8, Delta V is the voltage difference between the output of the supplemental power source 16 and the output of the converter 12, which ranges from 0 V to 1 V. Where the input power from the supplemental power source crosses recycled power in the energy recycling loop, the current in energy recycling loop is 0 Amps. In this example of the preferred embodiments of the present invention, the crossing point is the minimum amount of power that is needed from the supplemental power source to sustain the operation of the energy recycling loop.

The load current in the energy recycling loop can also be controlled by adjusting the parameters of the converter. Other suitable methods of controlling the load current magnitude and direction in the energy recycling loop, the loading effect of the inverter 14 on the converter 12, and the loading effect of the converter 12 on the inverter 14 can also be used.

The recycled load power, Pᵣ, outputted by the unit under test, which could be either the converter 12 or the inverter 14, is k times larger than the power delivered from the supplemental power source 16, Pₛ, according to the following formula:

Pᵣ=k*Pₛ

where k is a coefficient that is directly proportional to the combined system efficiency.

Thus, the energy regenerating systems 10, 21 of the preferred embodiments of the present invention possess at least one of the following fundamental differences when compared with conventional systems:
1. The supplemental power source 16 is connected to the DC terminals of the converter 12 and the inverter 14 and is not connected to the AC terminals of the converter 12 and the inverter 14;
2. The supplemental power source 16 can be a DC power source, which allows the power exchange into the energy recycling loop to be DC-to-DC and not AC-to-AC;
3. The load current in the energy recycling loop, the loading effect on the converter by the inverter, and the loading effect on the inverter by the converter can be varied as a function of the parameters of the supplemental power source 16 (preferably the output power), which allows the converter or the inverter 14 to act as an electronic load;
4. The energy regenerating system 10, 21 can be operated in facilities that do not have heavy duty wiring because only a fraction of the total power is needed to operate the energy regenerating system 10, 21, not the combined power of all the converters 12 and inverters 14. Only the energy regenerating system 10, 21 losses need to be replenished; and
5. The energy regenerating system 10 can be constructed for much less cost than conventional systems, while at the same time reducing electricity costs.

Because the power exchange is from DC-to-DC and not AC-to-AC, complicated and costly AC-to-AC devices, or AC-to-mains power merging and phase synchronizing devices are not required. In addition, simple inverters capable of providing modified sine wave, quasi sine wave, square wave, and/or any other acceptable alternating current waveforms can be used in the energy regenerating system 10, 21. The use of simple inverters eliminates the need for more expensive pure sine wave waveform converters that would be necessary if a utility AC-to-mains merging method is utilized.

The energy regenerating system 10, 21 of the preferred embodiments of the present invention enables economical full-power testing of various types of converters and inverters with a significant saving in electrical energy usage. Thus, the energy regenerating system 10, 21 has wide applications, especially in burn-in racks, life tests, ORT (Ongoing Reliability Tests), RDT (Reliability Demonstration Test), ATE (Automatic Test Equipment), converter testing, and inverter testing, as well as any electrical device modified for feeding back unused energy.

The energy regenerating systems 10 and 21 shown in FIGS. 3, 6, and 7 include a converter 12. Converter 12 is preferably an AC-to-DC power converter that inputs AC voltage and outputs a DC voltage. The energy regenerating systems 10 and 21 also include an inverter 14. Inverter 14 is preferably a DC-to-AC power converter that inputs a DC voltage and outputs an AC voltage. The converter 12 can include power factor correction circuitry. The AC voltage outputted by the inverter 14 can be in the form of a pure sine wave, modified sine wave, quasi sine wave, square wave, or any combination and/or derivative of the previously described waveforms that are suitable to be inputted into the converter 12.

The energy regenerating system 10, 21 according the preferred embodiments of the present invention also include a supplemental power source 16. The supplemental power source 16 can be an AC-to-DC converter, DC-to-DC converter, a battery, a solar panel, a wind turbine, any other suitable power source, or an array of such devices that is capable of outputting DC power to be inputted into the energy recycling loop.

An example of a preferred embodiment is shown in FIG. 6. In FIG. 6, the inverter 14 preferably acts as a load on the converter 12. The characteristics of this load are preferably varied as a function of the power applied to the input of the power inverter 14. By comparing FIGS. 4 and 6, the difference in power consumption between the conventional system 18 using a passive load 20 connected to converter 12 and the energy regenerating system 10 using an inverter 14 connected to converter 12 can be understood.

As discussed above with respect to FIG. 4, in the conventional system 18, 1100 W are lost, which includes 100 W dissipated by the converter 12 and 1000 W dissipated by the passive load resistor 20. In contrast, as shown in FIG. 6, according to the example of a preferred embodiment of the present invention, only 200 W are lost, which includes 100 W dissipated by the converter 12 and 100 W dissipated by the inverter 14. Thus, in this example, the power saving is about 900 W. The small losses of the supplemental power source 16, from wiring losses, from implementing control devices, etc. are neglected in this example because they represent only a small fraction of the recycled power.

In the preferred embodiments of the present invention, either the inverter 14 behaves like an electronic load with the additional function of converting the DC into AC voltage or the converter behaves like an electronic load with the additional function of converting the AC power into DC power. Thus, either the loading of the converter 12 and the converting of DC to AC or the loading of the inverter and the converting of AC to DC is done in one device, which improves the efficiency of the energy regenerating system 10, 21. The energy regenerating system 10, 21 preferably runs in a energy recycling loop that can be controlled and regulated to maintain precise current loading of the converter 12 or/and the inverter 14, depending on the requirements. Additional circuit may be required to achieve this control and regulation or to provide protection functions.

The preferred embodiments of the present invention can be implemented also by using either converters 12 or inverters 14 instead of industry standard electronic or resistive loads during testing, qualification, bench tests, and various other applications.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims.

What is claimed is:

1. An energy regenerating system comprising:
a converter;
an inverter; and
a supplemental power source; wherein
the converter and the inverter are electrically connected to each other to define an electrical loop such that energy of the energy regenerating system is regenerated;
the converter, the inverter, and the supplemental power source are arranged such that, when current flows in the electrical loop, the converter is a load on the inverter and the inverter is a load on the converter;
the supplemental power source is arranged to replenish energy losses in the energy regeneration system, including energy losses in the electrical loop caused by the converter and the inverter.

2. An energy regenerating system according to claim 1, wherein the supplemental power source outputs DC power.

3. An energy regenerating system according to claim 1, wherein the output of the supplemental power source is connected to DC terminals of the converter and the inverter.

4. An energy regenerating system according to claim 1 further comprising at least one additional converter arranged in an array with the inverter, converter, and supplemental power source; wherein
AC terminals of the inverter, the converter, and the at least one additional converter are connected.

5. An energy regenerating system according to claim 1 further comprising at least one additional inverter arranged in an array with the inverter, converter, and supplemental power source; wherein
DC terminals of the converter, the inverter, and the at least one additional inverter are connected.

6. An energy regenerating system according to claim 1, wherein the converter includes power factor correction circuitry.

7. An energy regenerating system according to claim 1, wherein the inverter outputs a pure sine wave, a modified sine wave, a quasi sine wave, a square wave, and/or a combination thereof.

8. An energy regenerating system according to claim 1, wherein the converter is arranged such that adjustments to parameters of the converter control a load current in the electrical loop.

9. An energy regenerating system according to claim 1, wherein the supplemental power source is arranged such that adjustments to parameters of the supplemental power source control a load current in the electrical loop.

10. An energy regenerating system according to claim 1, wherein the supplemental power source is arranged such that adjustments to parameters of the supplemental power source control the magnitude of a load current in the electrical loop.

11. An energy regenerating system according to claim 1, wherein the supplemental power source is arranged such that adjustments to parameters of the supplemental power source control the direction of a load current in the electrical loop.

12. An energy regenerating system according to claim 1, wherein an output of the supplemental power source and a DC terminal of the converter are configured to control a load current in the electrical loop.

13. An energy regenerating system according to claim 1, further comprising a control circuit arranged to control a load current in the electrical loop.

14. An energy regenerating system according to claim 1, further comprising a control circuit arranged to provide control, supervisory, measurement, or protection functions.

15. A method of testing a unit under test comprising the steps of:
providing a testing system including:
a converter;
an inverter; and
a supplemental power source; wherein
the unit under test is the converter, the inverter, or the supplemental power source;
connecting the converter and the inverter to each other to define an electrical loop such that energy is regenerated;
connecting the supplemental power source to the electrical loop to replenish energy losses in the testing system, including energy losses caused by the converter and the inverter; and
testing the unit under test by causing current to flow in the electrical loop.

16. A method of testing a unit under test according to claim 15, further comprising the step of adjusting at least one parameter of the supplemental power source to control a load current in the electrical loop.

17. A method of testing a unit under test according to claim 15, further comprising the step of adjusting at least one parameter of the supplemental power source to control the magnitude of a load current in the electrical loop.

18. A method of testing a unit under test according to claim 15, further comprising the step of adjusting the power output of the supplemental power source to control the magnitude of the load current in the electrical loop.

19. A method of testing a unit under test according to claim 15, further comprising the step of adjusting a voltage potential difference between an output of the supplemental power source and a DC terminal of the converter to control a load current in the electrical loop.

20. A method of testing a unit under test according to claim 15, further comprising the step of adjusting a voltage polarity between an output of the supplemental power source and a DC terminal of the converter to control a load current in the electrical loop.
